(19) United States
(12) Patent Application Publication
(10) Pub. No.: US 2002/0096692 A1
(43) Pub. Date: Jul. 25, 2002

(54) Insulating nitirde layer and process for its forming, and semiconductor device and process for its production

(76) Inventors: Fumihiko Nakamura, Kanagawa (JP); Hisayoshi Kuramochi, Kanagawa (JP); Hiroji Kawai, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/925,153

(22) Filed: Aug. 8, 2001

(30) Foreign Application Priority Data
Aug. 9, 2000 (JP) P2000-241581

(51) Int. Cl. H01L 21/00; H01L 31/0328; H01L 31/0336; H01L 31/072; H01L 31/109

(52) U.S. Cl. 257/194

(57) ABSTRACT

Disclosed herein is an insulating nitride layer suitable for group III-V nitride semiconductor devices. It has a high resistance and good insulating properties and hence it electrically isolates elements, without the active layer decreasing in conductivity. Disclosed also herein is a process for forming said nitride layer and a semiconductor device having said nitride layer for improved characteristic properties. The semiconductor device is an AlGaN/GaN HEMT or the like which has a GaN active layer and an insulating nitride layer formed thereon from a group III-V nitride compound semiconductor heavily doped mostly with a group IIB element (particularly Zn) in an amount not less than 1×10¹⁷/cm³.

### BACKGROUND OF THE INVENTION

The present invention relates to an insulating nitride layer and a process for its forming, and to a semiconductor device having said layer and a process for its production. (The insulating nitride layer refers specifically to one which is formed from a doped insulating group III-V compound semiconductor in the form of nitride.)

The semiconductor device based on a group III-V compound semiconductor in the form of nitride conventionally have an Mg-doped insulating GaN layer (with a high resistance) for electrical isolation of elements. For example, semiconductor devices such as MISFET (Metal Insulator Semiconductor Field Effect Transistor) and HEMT (High Electron Mobility Transistor, a kind of FET) composed of GaN and AlGaN consist of an insulating sapphire substrate and those layers sequentially formed thereon which include a low-temperature buffer layer of AlₓGa₁₋ₓN (0≦×≦1.0), a GaN layer (equal to or thicker than 1 μm), and GaN and AlGaN active layers forming a heterojunction interface.

A conventional practice to electrically isolate elements was to replace the underlying GaN layer with an Mg-doped GaN layer (Mg is a group IIA element), as mentioned by R. Dimitrov et al., Phys. Status Solidi A 168 (1998) R7. The disadvantage of doping GaN with Mg by MOCVD (organometallic chemical vapor deposition) is that hydrogen in the gas prevents Mg from becoming active, causing the Mg-doped GaN layer to have a high resistance, as reported by S. Nakamura et al., Jpn. J. Appl. Phys. 31 (1992) p. 1258-1266.

If Mg is supplied in the form of bis(methylcyclopentadienyl)magnesium ((MeCp)₂Mg) or bis(cyclopentadienyl)magnesium (Cp₂Mg), Mg enters by autodoping the active layer on the Mg-doped GaN layer, thereby decreasing the conductivity of the active layer.

A conventional HEMT that uses the AlGaN/GaN heterojunction is produced by sequentially forming the following layers on a sapphire substrate 1 as shown in FIG. 12. An undoped GaN-nucleating layer 2 (a buffer layer grown at a low temperature), 30-nm thick. An Mg-doped high-resistance GaN buffer layer 3a, 1.8-μm thick. An undoped GaN channel layer 4, 200-nm thick. An undoped AlGaN spacer layer 5, 3-nm thick. (There exists a heterojunction interface 14 between layers 4 and 5.) An n-AlGaN:Si carrier supply layer 6 (with n-type donor in concentration of 2.5×10¹⁸ cm⁻³), 20 nm thick. An undoped AlGaN cap layer 7, 15-nm thick. (The ratio (x) of Al in the composition is 0.2.) Incidentally, there are shown a source electrode 11, a gate electrode 12, and a drain electrode 13. Those parts right under the source and drain electrodes are alloyed for ohmic contact with the channel layer 4, although they are not shown in this and other figures. The spacer layer 5 isolates the channel layer 4 from the donor (Si) in the carrier supply layer 6.

As mentioned above, an HEMT is a high-speed field effect transistor (FET) which uses a heterojunction. It is characterized in that the heterojunction 14 spatially separates the crystal region (GaN layer 4) for electron movement and the crystal region (n-AlGaN layer 6) for electron supply from each other. This separation reduces the scattering of electrons by donor impurity (due to the absence of donor impurity in the GaN layer 4), thereby increasing the electron mobility between the source and the drain.

In actuality, however, the two-dimensional electron gas that occurs at the heterojunction decreases in concentration (nₛ) and mobility (as shown in FIG. 9) and hence the active layer 4 decreases in conductivity. This aggravates the characteristics of the device.

It was found that the foregoing problem arises from Mg (not less than 10¹⁷/cm³) entering the undoped GaN channel layer 4 which lies on the Mg-doped GaN buffer layer 3a, as evidenced by SIMS (secondary ion mass spectroscopy) shown in FIG. 13. This explains the cause for decrease in carrier concentration and mobility in the active layer.

A probable reason for this is that the reactant gas for Mg has a vapor pressure as low as 0.5 mmHg and hence it takes a long time to completely purge the reactant gas which has been adsorbed into the pipe and reactor. The reactant gas remaining adsorbed into the pipe is released while the undoped GaN channel layer 4 is grown on the GaN buffer layer 3a, and the thus released Mg enters the GaN channel layer 4 by autodoping.

One way to cope with this situation is to replace the Mg-doped GaN buffer layer 3a with the undoped GaN buffer layer 3b (2.0 μm thick) and grow thereon the undoped AlGaN spacer layer 5 (3 nm thick), the n-AlGaN:Si carrier supply layer 6 (20 nm thick), and the undoped AlGaN cap layer 7 (15 nm thick), with the undoped GaN channel layer 4 omitted, as shown in FIG. 14. The result is a high mobility as shown in FIG. 9, without the active layer decreasing in conductivity. Unfortunately, the undoped GaN buffer layer 3b is poor in insulating performance, with its sheet resistivity being only 10 kΩ.

### SUMMARY OF THE INVENTION

It is an object of the present invention to provide a nitride layer suitable for group III-V nitride compound semiconductor devices, the nitride layer being superior in insulating performance with high resistivity, permitting good electrical isolation of elements, without the active layer decreasing in conductivity. It is another object of the present invention to provide a process for forming the nitride layer. It is further another object of the present invention to provide an improved semiconductor device having the nitride layer.

The present invention is directed to an insulating nitride layer formed from a group III-V nitride compound semiconductor heavily doped mostly with a group IIB element. The present invention is directed also to a semiconductor device having the nitride layer.

The present invention is directed also to an improved process for forming a layer of group III-V nitride compound semiconductor by vapor deposition, wherein the improvement comprising feeding a reactant gas for the group III-V compound semiconductor together with a gas containing an impurity whose vapor pressure is equal to or higher than 10 mmHg at room temperature, thereby forming an insulating nitride layer which is heavily doped with the impurity.

The present invention is directed also to a process for producing a semiconductor device, the process comprising a step of forming a layer of group III-V nitride compound semiconductor by vapor deposition from a reactant gas for the group III-V compound semiconductor which is fed together with a gas containing an impurity whose vapor pressure is equal to or higher than 10 mmHg at room temperature, thereby forming an insulating nitride layer which is heavily doped with the impurity, and a step of growing an active layer on the insulating nitride layer by vapor deposition.

The present invention produces its effect when applied to MISFET elements or HEMT elements in which the underlying layer of the channel layer is a nitride layer which has good insulating performance owing to an impurity doped therein. The advantage of this nitride layer is its good insulating performance and its ability to isolate elements completely due to heavy doping with a group IIB element (particularly zinc). Another advantage is that the reactant gas of group IIB element used to form the nitride layer has a high vapor pressure (particularly equal to or higher than 10 mmHg). In other words, the process can use a reactant gas for impurity doping that is readily purged. As a result, the reactant gas for impurity doping is rapidly released when the active layer is formed on the insulating nitride layer by vapor deposition. This protects the active layer from autodoping with an impurity. The result is easy production of high-speed elements, without the active layer decreasing in conductivity.

As mentioned above, the insulating nitride layer heavily doped with an impurity can be readily obtained by doping the group III-V nitride compound semiconductor with an impurity (such as Zn). In this way it is possible to form a highly insulating nitride layer whose resistivity (sheet resistance) is equal to or higher than 0.3 MΩ, without causing the active layer to decrease in conductivity. This insulating nitride layer contributes to high-speed elements. See FIG. 9. Moreover, it can be used for element isolation in group III-V compound semiconductor devices. It is also useful for high-speed transistors if it is formed under the channel layer of MISFET or HEMT elements.

### BRIEF DESCRIPTION OF THE DRAWINGS

FIG. 1 is a schematic sectional view showing the structure of a sample of an AlGaN/GaN HEMP having an insulating nitride layer according to the present invention;

FIG. 2 is a schematic sectional view showing the structure of the same sample as above used to evaluate how steeply the Mg- or Zn-doping changes at the interface;

FIG. 3 is a graph showing the result of SIMS analysis which indicates how steeply the Mg- or Zn-doping changes at the interface in the same sample as above;

FIG. 4 is a schematic sectional view showing the structure of the same sample as above used to evaluate the concentration of doped Mg or Zn;

FIG. 5 is a graph showing the concentration of various dopants in the same sample as above;

FIG. 6 is a graph showing how the sheet resistance changes depending on the Zn concentration in the same sample as above;

FIG. 7 is a graph showing the Zn concentration compared with the C concentration in the same sample as above;

FIG. 8 is a graph showing how the carrier concentration changes depending on depth in an AlGaN/GaN HEMP which has the insulating nitride layer according to the present invention;

FIG. 9 is a graph showing the relation between the sheet carrier concentration (nₛ) and the mobility in an AlGaN/GaN HEMP;

FIG. 10 is a schematic sectional view showing an example of the structure of an MISFET according to the present invention;

FIG. 11 is a schematic sectional view showing an example of the structure of a GaN MESFET according to the present invention;

FIG. 12 is a schematic sectional view showing the structure of a conventional AlGaN/GaN HEMT;

FIG. 13 is a graph showing the result of SIMS analysis of Mg in a HEMT; and

FIG. 14 is a schematic sectional view showing the structure of an AlGaN/GaN HEMT formed on an undoped GaN buffer layer.

### DETAILED DESCRIPTION OF THE PREFERRED EMBODIMENTS

According to the present invention to achieve the above-mentioned object, it is desirable that the insulating nitride layer should be heavily doped with a group IIB element (substantially a group IIB element alone or at least Zn) as an impurity.

The amount of the group IIB element to be added should preferably be not less than 1×10¹⁷/cm³ so that the nitride layer has a sufficiently high resistance for practical use. More preferably, it should be equal to or higher than 1×10¹⁸/cm³ so that it keeps a sufficiently high resistance regardless of the level of undoping by carriers contained in the layer.

The above-mentioned impurity is supplied from a reactant gas containing a compound of a group IIB element (at least Zn). It is essential that the reactant gas should have a vapor pressure equal to or higher than 10 mmHg at room temperature. Any reactant gas having a vapor pressure lower than specified above presents difficulties in purging and is liable to cause autodoping. The reactant gas having a high vapor pressure is exemplified by alkyl zinc such as diethyl zinc (DEZn) and dimethyl zinc (DMZn).

The amount of the above-mentioned impurity to be doped should preferably be not less than 1×10¹⁷/cm³, more preferably not less than 1×10¹⁸/cm³. For example, Zn as an impurity should be added in an amount not less than 1×10¹⁷/cm³ when the crystal of group III-V nitride compound semiconductor is grown by organometallic vapor phase epitaxy. The upper limit of the amount is determined by the saturated concentration of impurity dissolved in the matrix.

The substrate on which the insulating nitride layer is grown should preferably be an insulating one of sapphire. However, it may be replaced with a conducting one of SiC or the like.

Table 1 below shows the vapor pressure of various organometallic compounds. It is to be noted that the requirement that the reactant gas to dope the nitride layer should have a vapor pressure equal to or higher than 10 mmHg at room temperature is met by not only DEZn and DMZn but also dimethyl cadmium.

TABLE 1

| Im- | Organometallic | | | | |
|---|---|---|---|---|---|
| purity | compound | Chemical | | | |
| element | gas | formula | Vapor pressure | | Remarks |
| Cd | Dimethyl | (CH₃)₂Cd | 28.4 | mmHg | |
| | cadmium | | | at | |
| | | | | 20° C. | |
| Mg | Bis(cyclopenta- | (C₅H₅)₂Mg | 0.03 | mmHg | |
| | dienyl)- | or Cp₂Mg | | at | |
| | magnesium | | | 20° C. | |
| Mg | Bis(methylcyclo- | (CH₃C₅H₄)₂Mg | 0.44 | mm Hg | Melts at |
| | pentadienyl)- | or (MeCp)₂Mg | | at | 29° C. |
| | magnesium | | | 35° C. | |
| Zn | Diethyl zinc | (C₂H₅)₂Zn | 302 | mmHg | |
| | | | | at | |
| | | | | 20° C. | |
| Zn | Dimethyl zinc | (CH₃)₂Zn | 12.2 | mmHg | |
| | | | | at | |
| | | | | 20° C. | |

In the present invention, the group III-V nitride compound semiconductor mentioned above may be GaN, AlN, InN, or BN, or a mixture thereof. They are converted into insulating nitrides upon doping with a group IIB element, and such nitrides constitute other layers in the group III-V compound semiconductor device.

In other words, the semiconductor device according to the present invention employs the above-mentioned group III-V nitride compound semiconductor as at least part of its constituents. The insulating nitride layer is used to isolate not less than one kind of integrated elements including field effect transistor, bipolar transistor, light-emitting diode, semiconductor laser, and photodiode.

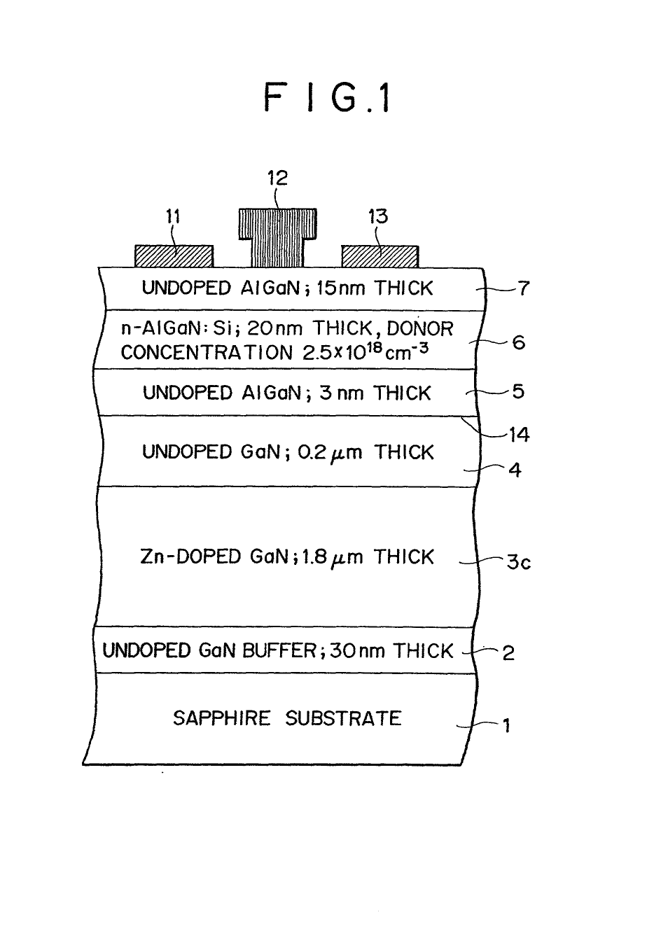

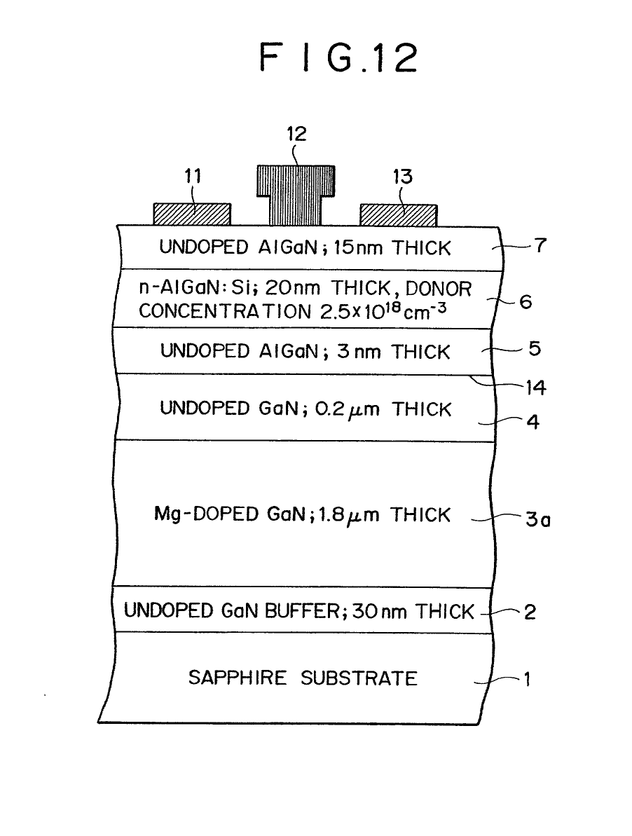

The structure of HEMT according to the present invention is shown in FIG. 1. It is basically different from the conventional one shown in FIG. 12. The difference is that the undoped GaN nucleating layer 2 has the Zn-doped GaN buffer layer 3c (which has a resistance equal to or higher than 0.3 MΩ) and the GaN channel layer 4 sequentially grown thereon.

The advantage of this structure is that the Zn-doped GaN buffer layer 3c under the active layer 4 has a sufficiently high resistance and hence effectively isolates other elements (not shown) formed on the common sapphire substrate 1. Moreover, the Zn-doped buffer layer 3c protects the active layer 4 from autodoping with an impurity as mentioned above and keeps its conductivity adequately.

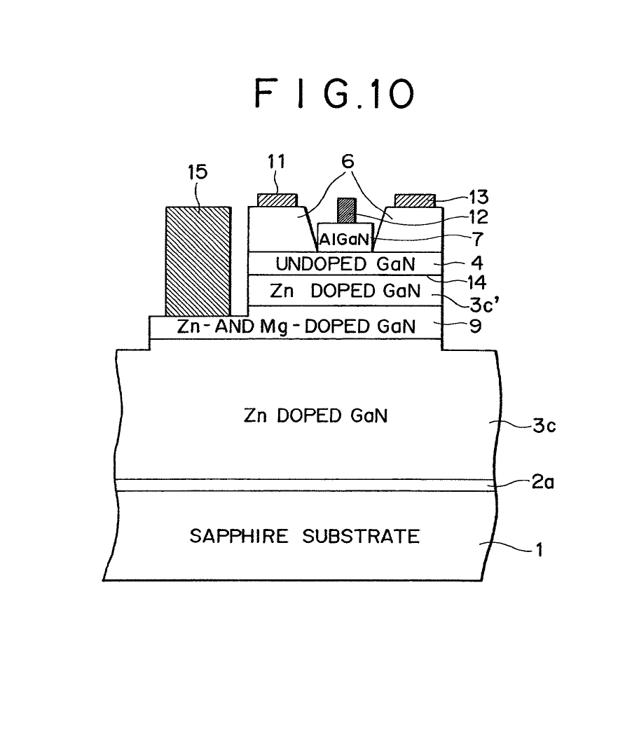

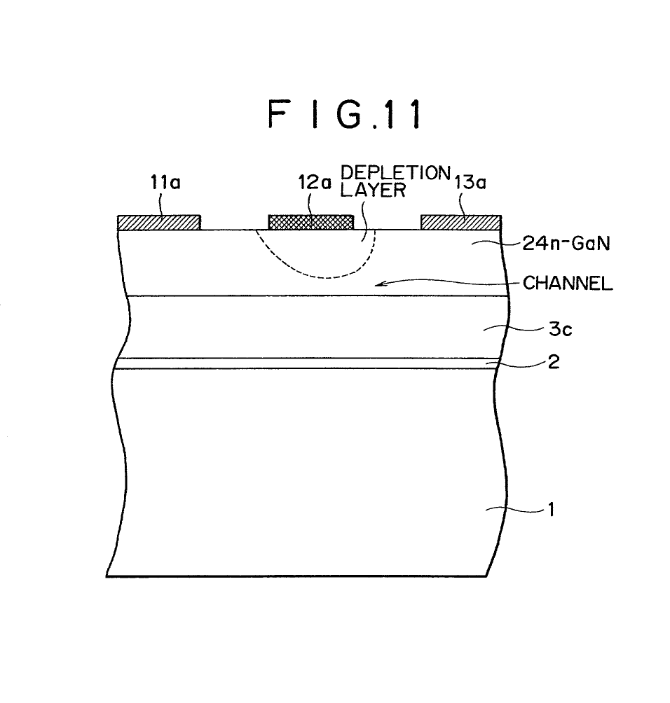

The present invention can also be applied to MISFET (metal insulator semiconductor field effect transistor) and MESFET (metal semiconductor field effect transistor), whose structure is shown in FIGS. 10 and 11, respectively. They will be explained later.

The present invention can be applied to any device of mesa structure or planar structure which needs element isolation. The device is not limited in structure and material.

The invention will be described with reference to the following examples.

### EXAMPLE 1

A semiconductor sample was prepared which consists of thin layers formed on the (0001) C plane of a sapphire substrate. The substrate was heated under normal pressure in a horizontal furnace for metal organic vapor phase epitaxy. The furnace was supplied with a reactant gas composed of trimethyl gallium (TMGa), ammonia (NH₃), bis-(methylcylcopentadienyl)magnesium ((MeCp)₂Mg), and diethyl zinc (DEZn). The ratio of group V to group III is from about 2,400 to 12,000.

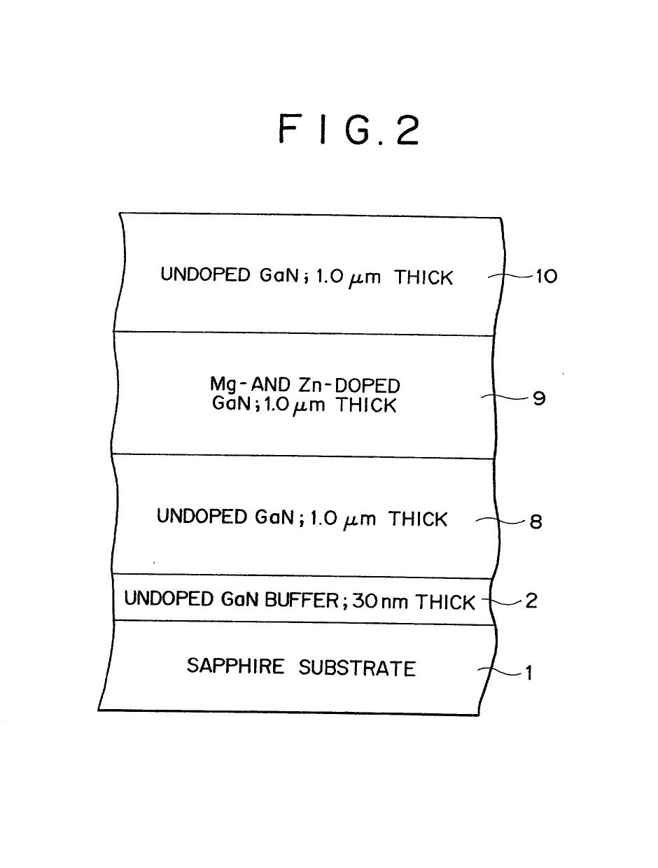

The resulting sample has the layer structure as shown in FIG. 2. There is shown the sapphire substrate 1. On the substrate is formed the GaN nucleating layer 2, which is 30 nm thick. On the GaN nucleating layer 2 are sequentially formed at a growing temperature of 1100° C. the undoped GaN layer 8, the Mg:Zn-codoped GaN layer 9, and the undoped GaN layer 10, which are all 1.0 μm thick. The mole fraction of TMGa and NH₃ is 6.5×10⁻⁵ and 0.4, respectively, so that the ratio of group V to group III is about 6000. The concentration of Mg and Zn is 3×10¹⁸/cm³ and 1×10⁸/cm³, respectively. These conditions are necessary for the insulating GaN layer to have a high resistance.

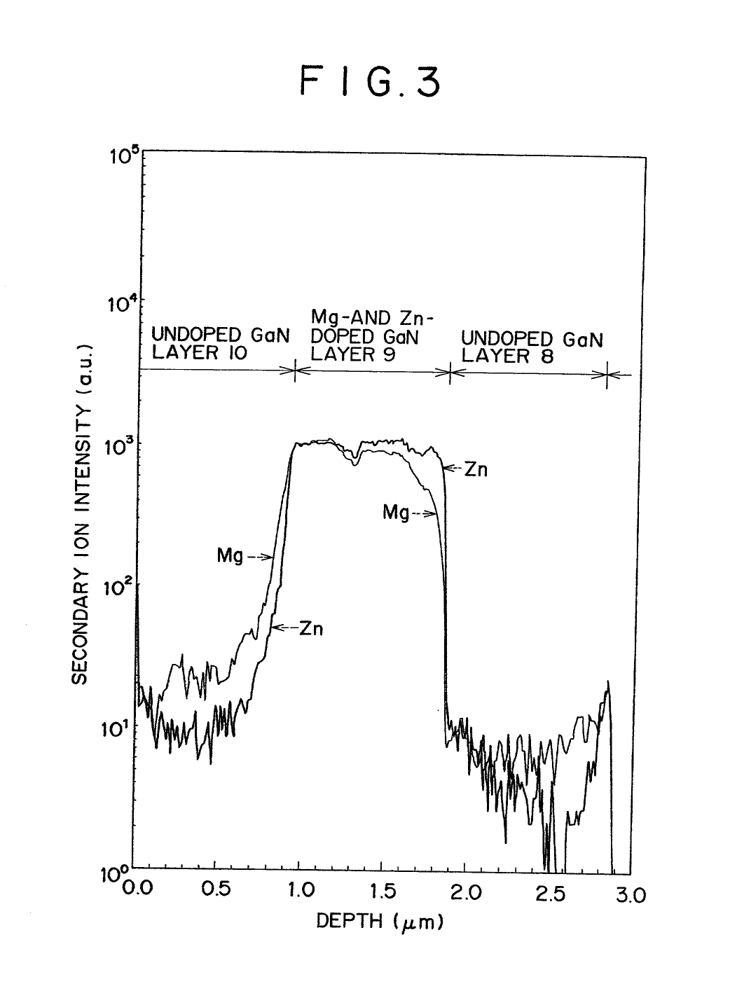

FIG. 3 shows the result of SIMS analysis for distribution of Mg and Zn concentrations. It is noted that the distribution of Zn has a steeper profile than that of Mg. It is also noted that Mg is slower than Zn in the rise and fall of concentration when doping starts and stops. In other words, there is a significant difference between Mg and Zn in the doping behavior. The concentration of Zn decreases to 1/100 whereas the concentration of Mg deceases to only 1/10 when measured at the position 0.2 μm away from the interface toward the surface.

The foregoing suggests that it is possible to form an insulating GaN layer having a steep profile if diethyl zinc (DEZn) is used as a dopant.

### EXAMPLE 2

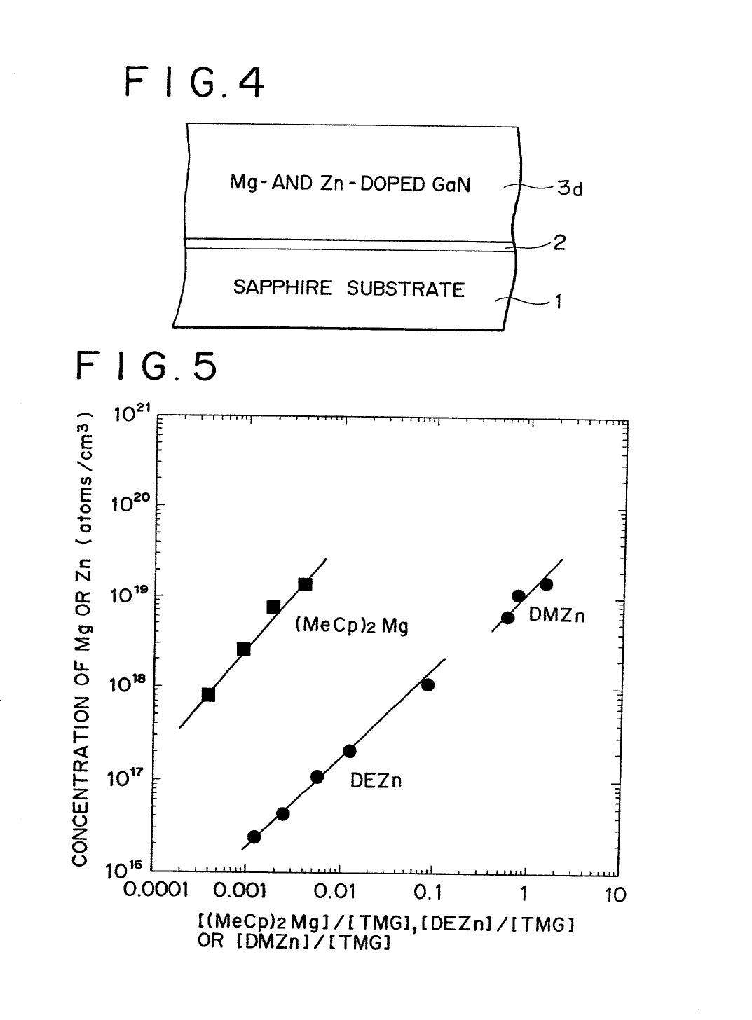

The sample in this example has the layer structure as shown in FIG. 4. There is shown the sapphire substrate 1. On the substrate is formed the GaN nucleating layer 2, which is 30 nm thick. On the GaN nucleating layer 2 are sequentially formed at a growing temperature of 1100° C. the Mg- or Zn-doped GaN layer 3d, which is 1.8-2.0 μm thick. The mole fraction of TMGa and NH₃ is 6.5×10⁻⁵ and 0.4, respectively, so that the ratio of group V to group III is about 6000. The mole fraction of (MeCp)₂Mg, DEZn, and DMZn ranges from 3×10⁻⁸ to 1×10⁻⁴.

FIG. 5 shows how the amount of reactant gas affects the concentration of Mg and Zn in the GaN layer. It is noted that the concentration of Zn smoothly ranges from 1×10¹⁶/cm³ to 1×10¹⁹/cm³. It is also noted that the concentration of Zn is two orders of magnitude smaller than that of Mg. It was found that the sample with a Zn concentration of 1×10¹⁸/cm³ has a sheet resistance equal to or higher than 0.3 MΩ.

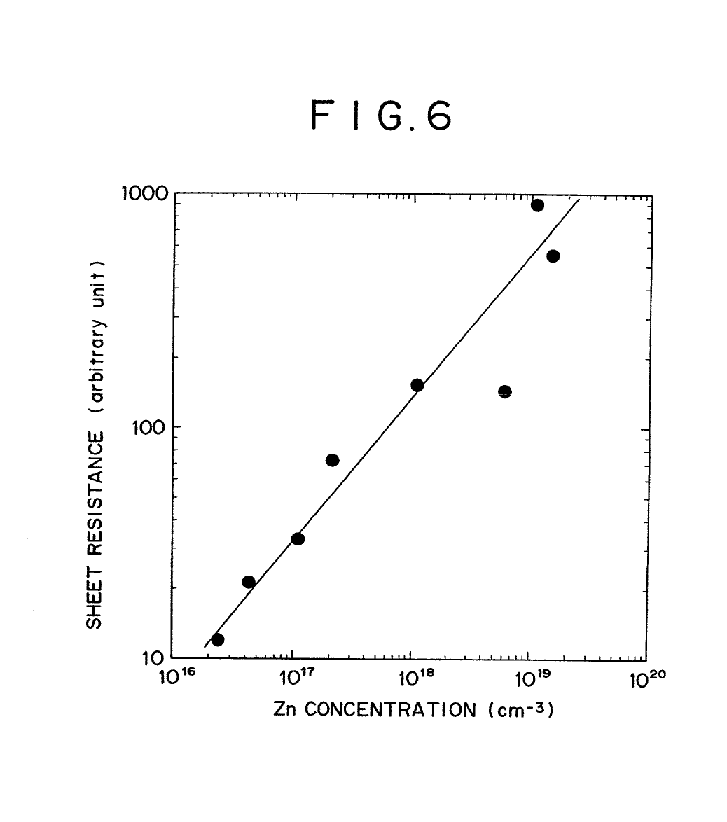

FIG. 6 shows the sheet resistance (in arbitrary units) vs. the Zn concentration. It is noted that the resistance increases in proportion to the Zn concentration.

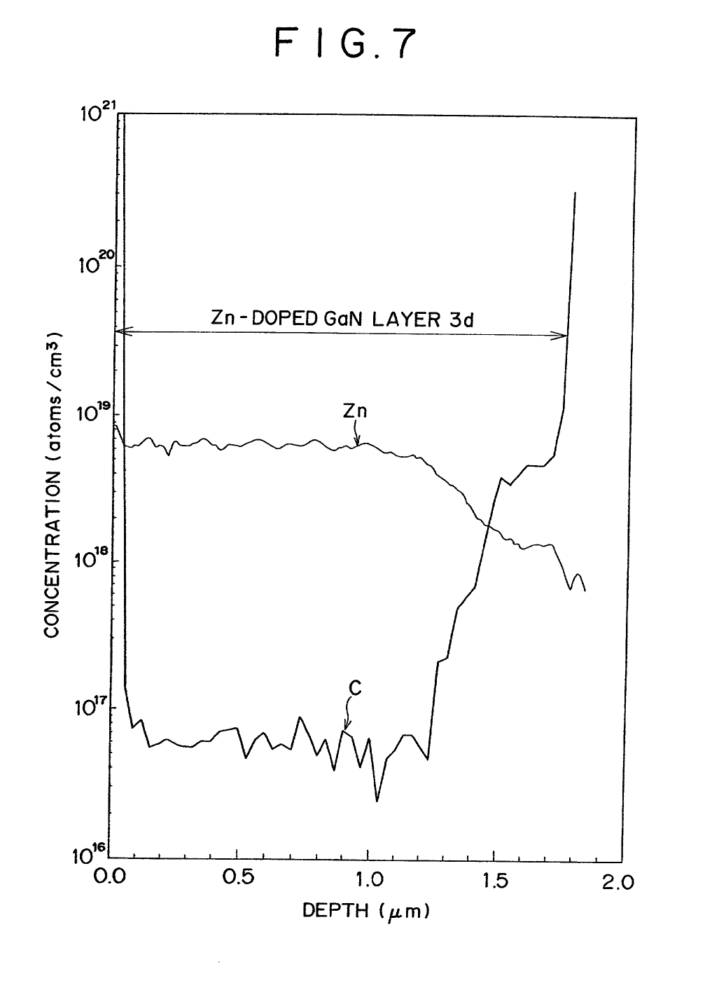

FIG. 7 shows the result of SIMS analysis for Zn and C concentrations in the Zn-doped GaN layer. It is noted that the Zn and C concentrations in the layer (except for the vicinity of the interface with the substrate and the outermost surface) are about 6×10¹⁸ atoms/cm³ and 6×10¹⁶ atoms/cm³, respectively. The foregoing result indicates that the C concentration in the layer formed under the above-mentioned condition is not more than 6×10¹⁶ atoms/cm³.

The fact that the C concentration is considerably low suggests that Zn is the major dopant. A probable reason for this that NH₃ as the reactant gas suppresses the doping with carbon. Moreover, the effect of suppressing the doping with carbon is enhanced when TMGa is replaced by triethyl gallium (TEGa) which readily decomposes and permits liberated carbon to be discharged easily.

### EXAMPLE 3

A sample of high electron mobility transistor (HEMT) was prepared which consists of thin layers formed on the (0001) C plane of a sapphire substrate. The substrate was heated under normal pressure in a horizontal furnace for metal organic vapor phase epitaxy (MOVPE). The furnace was supplied with a reactant gas composed of trimethyl gallium (TMGa), ammonia (NH₃), trimethyl aluminum (TMAl), and monomethylsilane (CH₃SiH₃). The ratio of group V to group III is from about 2,400 to 12,000.

The resulting sample has the layer structure as shown in FIG. 1. There is shown the sapphire substrate 1. On the substrate is formed the GaN nucleating layer 2, which is 30 nm thick. On the GaN nucleating layer 2 is formed the insulating GaN buffer layer 3c (1.8 μm thick) from TMGA at 1100° C. Vapor phase epitaxy is continued to sequentially form the GaN channel layer 4 (200 nm thick), the undoped AlGaN spacer layer 5 (3 nm thick), the n-AlGaN carrier supply layer 6 (20 nm thick), and the undoped AlGaN gap layer 7 (15 nm thick). The Zn-doped insulating GaN buffer layer 3c (which was formed from diethyl zinc as a reactant gas) has a Zn concentration equal to or higher than 1×10¹⁸/cm³ and a sheet resistance equal to or higher than 0.3 MΩ.

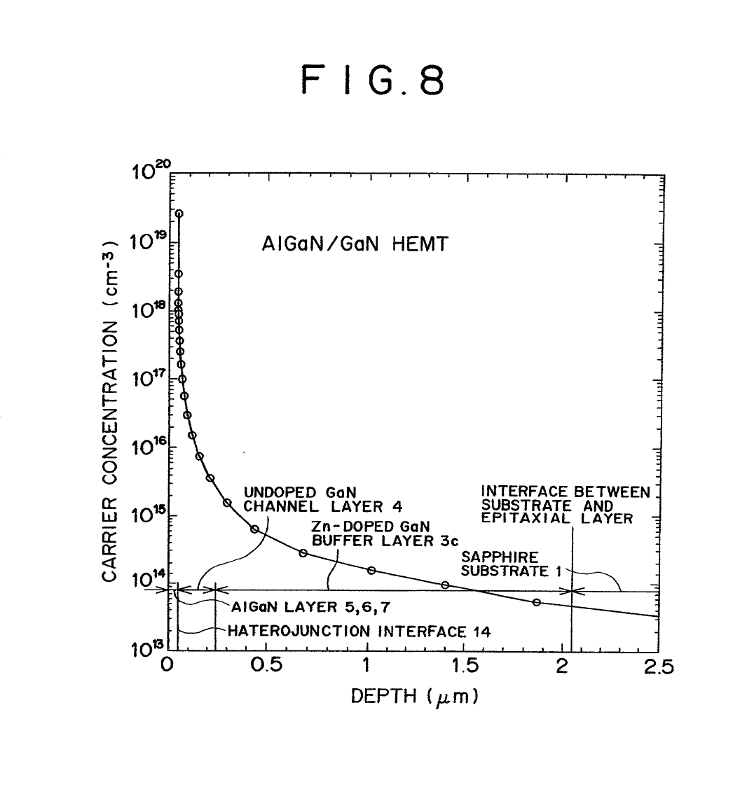

The sample was tested for the distribution of carrier concentrations in the depth direction by the C-V method. The results are shown in FIG. 8. It is noted that the carrier concentration at the hetero interface of the active layer 4 exceeds 1×10¹⁹/cm³, whereas that in the Zn-doped GaN layer 3c is equal to or lower than 1×10¹⁵/cm³.

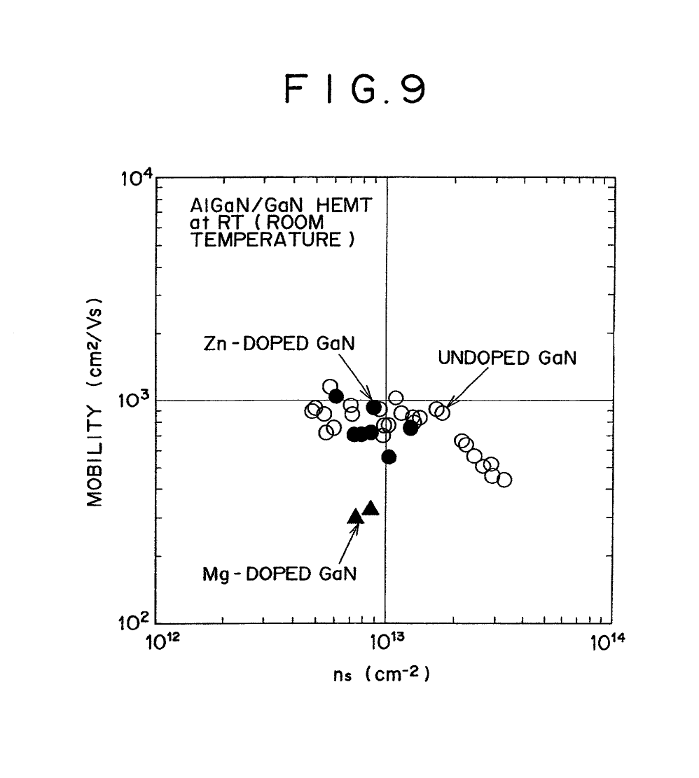

It is noted from FIG. 9 that the concentration (nₛ) and mobility of the two-dimensional electron gas that occurs at the heterojunction are identical with those in the case where the undoped GaN buffer layer is used. It was also found that the conductivity of the active layer does not decrease.

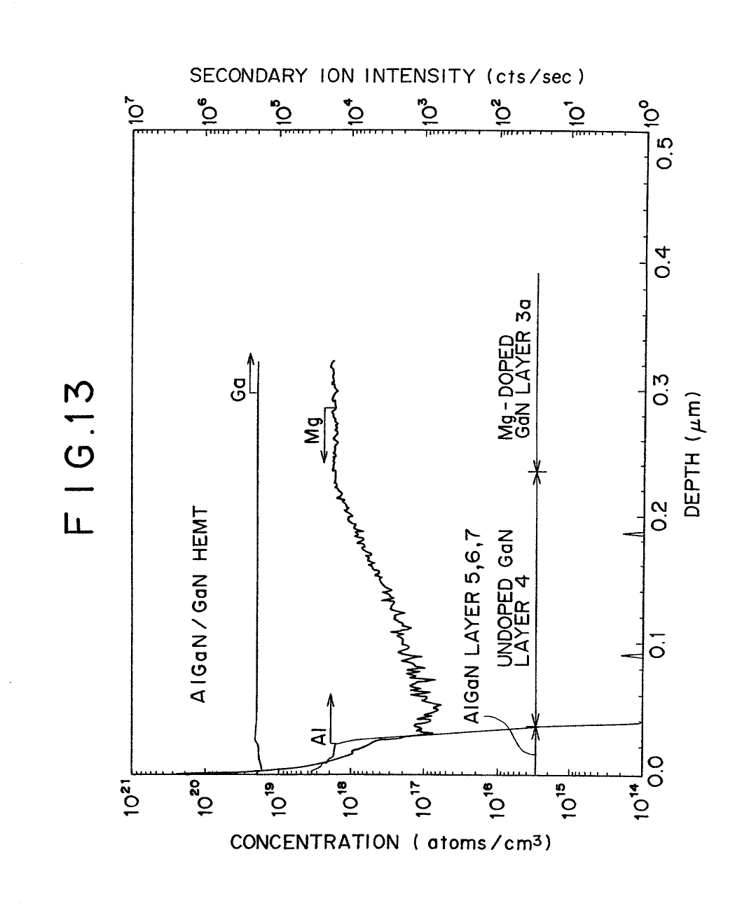

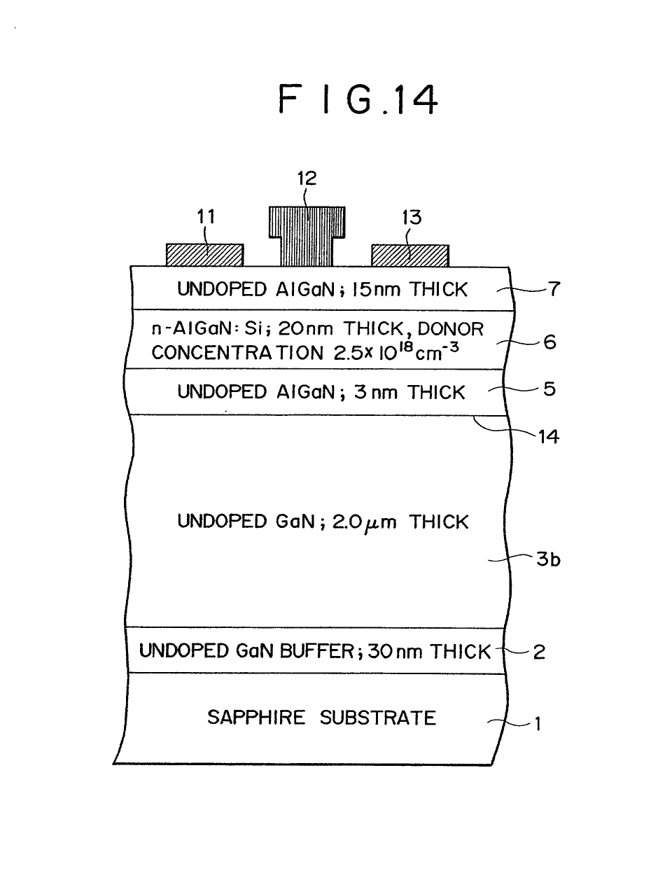

The sample with a gate electrode 12 (whose gate length (d) is 1.0 μm) gave a maximum cut-off frequency of 10 GHz. This value is better than 9 GHz achieved by the sample (shown in FIG. 13) which has the Mg-doped insulting GaN buffer layer 3a.

### EXAMPLE 4

A sample of transistor (MISFET) was prepared which consists of thin layers formed on the (1120) A plane of a sapphire substrate. The substrate was heated under normal pressure in a horizontal furnace for metal organic vapor phase epitaxy. The furnace was supplied with a reactant gas composed of trimethyl gallium (TMGa) ammonia (NH₃), trimethyl aluminum (TMAl), and monomethylsilane (CH₃SiH₃) The ratio of group V to group III is from about 2,400 to 12,000.

The resulting sample has the layer structure as shown in FIG. 10. There is shown the sapphire substrate 1. On the substrate is formed at about 600° C. the AlN nucleating layer 2a, which is 50 nm thick. On the GaN nucleating layer 2a is formed the Zn-doped insulating GaN buffer layer 3c (equal to or thicker than 1 μm) from diethyl zinc (as a dopant gas) at 1100° C. The GaN buffer layer 3c has a Zn concentration equal to or higher than 1×10¹⁸/cm³ and a sheet resistance equal to or higher than 0.3 MΩ.

Vapor phase epitaxy is continued to sequentially form the Zn:Mg-codoped GaN layer 9 (about 1 μm thick), the Zn-doped insulating GaN buffer layer 3c′ (equal to or thicker than 300 nm), the GaN channel layer 4 (200 nm thick), and the undoped AlGaN insulating layer 7 (40 nm thick).

The Zn:Mg-codoped GaN layer 9 has an Mg concentration equal to or higher than 1×10¹⁹/cm³, and it is subsequently activated by electron beam irradiation to form a p-type conducting layer. The buffer layer 3c′ of the same composition as the buffer layer 3c has a Zn concentration equal to or higher than 1×10¹⁸/cm³.

Subsequently, the undoped AlGaN insulating layer 7 undergoes reactive ion etching (RIE) through a mask of SiO₂. On the etched part is grown the Si-doped GaN layer 6 for source and drain contact.

Masking and etching are carried out to fabricate the Zn-doped GaN layer 3c′, to surface the Zn:Mg-codoped GaN layer 9, to isolate elements by the GaN layers 3c′, 9, and 3c, and to form the electrodes 11, 12, 13, and 15.

The FET obtained as mentioned above has its channel frequency characteristics controlled by the lead electrode 15 (which is the fourth electrode).

In this example, too, it was confirmed that the two-dimensional electron gas that occurs at the heterojunction is identical in concentration and mobility with that in the example in which the undoped GaN buffer layer is used. It was also confirmed that the active layer in this example dose not decrease in conductivity.

### EXAMPLE 5

This example demonstrates a GaN MESFET to which the present invention is applied. Its layer structure is shown in FIG. 11. It consists of the high-resistance Zn-doped GaN buffer layer 3c (few μm thick) and the n-type active layer 24 (0.2-0.5 μm), which are formed by vapor phase epitaxy on the substrate 1. On the top layer are formed the source electrode 11a, the drain electrode 13a, and the rectifying Schottky gate 12a. The GaN MESFET works in such a way that the gate voltage changes the thickness of the electron depletion layer under the gate, thereby controlling the source-drain current.

The present invention is characterized in that the insulating nitride layer is formed by heavily doping with a group IIB element (particularly Zn) as an impurity. The thus doped nitride layer has good insulating properties necessary for complete element isolation. Another advantage is that the reactant gas for the group IIB element has such a high vapor pressure that it can be readily purged when the nitride layer is formed. Thus the reactant gas for impurity is completely released when the active layer is formed by vapor phase epitaxy on the insulating nitride layer. In this way the active layer is protected from autodoping with impurity, with the result that the active layer keeps its conductivity high and the completely isolated elements work at high speeds.

What is claimed is:

1. An insulating nitride layer formed from a group III-V nitride compound semiconductor heavily doped mostly with a group IIB element.

2. An insulating nitride layer as defined in claim 1, which is heavily doped substantially with said group IIB element as an impurity.

3. An insulating nitride layer as defined in claim 2, which is heavily doped with at least zinc among said group IIB elements.

4. An insulating nitride layer as defined in claim 1, which is doped with said group IIB element in an amount not less than 1×10¹⁷/cm³.

5. An insulating nitride layer as defined in claim 1, in which said group III-V nitride compound semiconductor is GaN, AlN, InN, or BN, or a mixture thereof.

6. An improved process for forming a layer of group III-V nitride compound semiconductor by vapor deposition, wherein said improvement comprising feeding a reactant gas for said group III-V compound semiconductor together with a gas containing an impurity whose vapor pressure is equal to or higher than 10 mmHg at room temperature, thereby forming an insulating nitride layer which is heavily doped with said impurity.

7. A process for forming an insulating nitride layer as defined in claim 6, in which said impurity-containing gas is mainly a compound gas of group IIB element.

8. A process for forming an insulating nitride layer as defined in claim 7, in which said impurity-containing gas is substantially a compound gas of group IIB element.

9. A process for forming an insulating nitride layer as defined in claim 8, in which said compound gas is a gas of zinc compound.

10. A process for forming an insulating nitride layer as defined in claim 9, in which said compound gas is an alkyl zinc such as diethyl zinc and dimethyl zinc.

11. A process for forming an insulating nitride layer as defined in claim 6, in which said impurity is added in an amount not less than 1×10¹⁷/cm³.

12. A process for forming an insulating nitride layer as defined in claim 6, in which said group III-V nitride compound semiconductor is GaN, AlN, InN, or BN, or a mixture thereof.

13. A semiconductor device which has an insulating nitride layer formed from a group III-V nitride compound semiconductor heavily doped mostly with a group IIB element.

14. A semiconductor device as defined in claim 13, in which said group III-V nitride compound semiconductor is used at least part of its constituents for isolation of one or more kinds of integrated elements including field effect transistor, bipolar transistor, light-emitting diode, semiconductor laser, and photodiode.

15. A semiconductor device as defined in claim 13, in which an active layer is formed on said insulating nitride layer.

16. A semiconductor device as defined in claim 13, in which the insulating nitride layer is heavily doped substantially with said group IIB element as an impurity.

17. A semiconductor device as defined in claim 16, in which the insulating nitride layer is heavily doped with at least zinc among said group IIB elements.

18. A semiconductor device as defined in claim 13, in which the insulating nitride layer is doped with said group IIB element in an amount not less than 1×10¹⁷/cm³.

19. A semiconductor device as defined in claim 13 or 14, in which said group III-V nitride compound semiconductor is GaN, AlN, InN, or BN, or a mixture thereof.

20. A process for producing a semiconductor device which has an insulating nitride layer formed from a group III-V nitride compound semiconductor heavily doped mostly with a group IIB element, said process comprising a step of forming a layer of group III-V nitride compound semiconductor by vapor deposition from a reactant gas for said group III-V compound semiconductor which is fed together with a gas containing an impurity whose vapor pressure is equal to or higher than 10 mmHg at room temperature, thereby forming an insulating nitride layer which is heavily doped with said impurity, and a step of growing an active layer on said insulating nitride layer by vapor deposition.

21. A process for producing a semiconductor device as defined in claim 20, in which said group III-V nitride compound semiconductor is used at least part of its constituents for isolation of one or more kinds of integrated elements including field effect transistor, bipolar transistor, light-emitting diode, semiconductor laser, and photodiode.

22. A process for producing a semiconductor device as defined in claim 20, in which said impurity-containing gas is mainly a compound gas of group IIB element.

23. A process for producing a semiconductor device as defined in claim 22, in which said impurity-containing gas is substantially a compound gas of group IIB element.

24. A process for producing a semiconductor device as defined in claim 23, in which said compound gas is a gas of zinc compound.

25. A process for producing a semiconductor device as defined in claim 24, in which said compound gas is an alkyl zinc such as diethyl zinc and dimethyl zinc.

26. A process for producing a semiconductor device as defined in claim 20, in which said impurity is added in an amount not less than 1×10¹⁷/cm³.

27. A process for producing a semiconductor device as defined in claim 20, in which said group III-V nitride compound semiconductor is GaN, AlN, InN, or BN, or a mixture thereof.
